(19) United States
(12) Patent Application Publication
(10) Pub. No.: US 2024/0021436 A1
(43) Pub. Date: Jan. 18, 2024

(54) METHOD AND APPARATUS FOR MANUFACTURING A TERMINAL APPARATUS FOR CONNECTING AT LEAST ONE ELECTRICAL OR ELECTRONIC COMPONENT FOR AN ELECTRICAL OR ELECTRONIC MODULE

(71) Applicant: ZF Friedrichshafen AG, Friedrichshafen (DE)

(72) Inventors: Ake Ewald, Bayreuth (DE); Fabian Hohmann, Hofbieber (DE); Stefan Hain, Speichersdorf (DE)

(73) Assignee: ZF Friedrichshafen AG, Friedrichshafen (DE)

(21) Appl. No.: 18/353,611

(22) Filed: Jul. 17, 2023

(30) Foreign Application Priority Data
Jul. 18, 2022 (DE) 102022207270.7

(51) Int. Cl. H01L 21/48; H01L 23/495; H01L 23/00; B60K 1/00; B60K 23/00

(52) U.S. Cl. CPC H01L 21/4842; H01L 23/49551; H01L 24/35; H01L 24/37; H01L 24/744; B60K 1/00; B60K 23/00; H01L 24/40; H01L 2224/37013; H01L 2224/352; H01L 2224/40137; H01L 2224/48225; H01L 24/48; H01L 24/73; H01L 2224/73221; H01L 2224/37011

(57) ABSTRACT

A method for manufacturing a terminal apparatus for connecting a component for an electrical module includes bending a pre-machined sheet metal element, having a first electric terminal device for connecting to a first potential, a control terminal having a control contact, and a second electric terminal device arranged between the first electric terminal device and the control terminal and separated from the first electric terminal device by a gap, and for connecting to a second electrical potential, further having a path section including a first path for contact-connection with a terminal for the second electrical potential of the component, and a second path arranged in parallel with the first, and wherein an edge region of the sheet metal is bent such that the first electric terminal device and the path section are brought together such that the first electric terminal device and the path section overlap.

### CROSS-REFERENCE TO RELATED APPLICATION

This application claims priority to German Application No. DE 10 2022 207 270.7, filed on Jul. 18, 2022, the entirety of which is hereby fully incorporated by reference herein.

### FIELD

The approach described herein relates to a method for manufacturing a terminal apparatus for connecting at least one electrical or electronic component for an electrical or electronic module, an apparatus for the actuation and/or execution of the method, a method for manufacturing an electrical or electronic module, a power converter, an electric axle drive for a motor vehicle, and a motor vehicle.

### BACKGROUND AND SUMMARY

Conventionally, in the field of power converters for electric axle drives of motor vehicles or, in other words, in the field of traction inverters for automobile applications, integrated B6 bridge modules, integrated half-bridge modules or discrete individual switches can be employed. In this connection, US2021313243A1 discloses a module having a leadframe, i.e. a connecting frame. The positioning of semiconductor components is thus substantially driven by the manufacturability of the leadframe which, in the original draft document, is represented in one instance as a sheet metal component. Outgoing currents, for example, can be divided between two terminals, thereby resulting in a potentially non-uniform distribution of currents and a consequent differential loading of semiconductors.

In this context, the approach described herein provides an improved method for manufacturing a terminal apparatus for connecting at least one electrical or electronic component for an electrical or electronic module, an improved apparatus for actuating and/or executing the method, an improved method for manufacturing an electrical or electronic module, an improved power converter, an improved electric axle drive for a motor vehicle and an improved motor vehicle, as claimed in the main claims. Advantageous configurations proceed from the sub-claims, and from the following description.

By means of the method proposed herein, a shortening of the leadframe can be achieved, such that connecting elements at different potentials can be mutually arranged in closer proximity within the module than in existing systems.

Advantages achievable by means of the approach envisaged are particularly provided in that an in-module semiconductor contact-connection of a power module of a power converter for an electric axle drive of a motor vehicle can be achieved in an advantageous manner. By way of distinction from a module based upon a conventional leadframe design, according to embodiments of the power module, it can be achieved, for example, that current conduction between semiconductor components, more specifically between power semiconductor components in the region of the “power source” or, in other words, a connection or power connection of semiconductor components, is executed in a consistent manner. Thus, in particular, a uniform distribution of electric currents can be achieved, as a result of which a consistent loading of semiconductors is obtainable. According to embodiments, for example, a power module can be executed which comprises a centralized source tap or, in other words, a power terminal which is centrally or medially arranged with respect to a plurality of power semiconductor components. Thus, in particular, by means of the central power-source connection, a uniform current distribution between power semiconductor components is permitted. Moreover, particularly in the power module, a connection of all control terminals of power semiconductor components to a corresponding terminal pin of the power module can be provided.

A method for manufacturing a terminal apparatus for connecting at least one electrical or electronic component for an electrical or electronic module comprises a bending step. In the bending step, a pre-machined sheet metal element is bent, having a first electric terminal device for connecting to a first electrical potential, a control terminal having at least one control contact, and a second electric terminal device which is arranged between the first electric terminal device and the control terminal and is separated from the first electric terminal device by a gap, for connecting to a second electrical potential, wherein the second electric terminal device has a path section which comprises a first path for contact-connection with a terminal for the second electrical potential of the electrical or electronic component, and at least one second path which is arranged in parallel with the first path. In the bending step, an edge region of the sheet metal is bent such that the first electric terminal device and the path section are brought together, and the terminal apparatus is thus formed by the overlapping arrangement of the first electric terminal device and the path section.

This method can be implemented, for example, in a hardware or in a software, or in a hybrid arrangement of software and hardware, for example in a control device.

The terminal apparatus can be a leadframe, i.e., for example, a metallic terminal frames. The sheet metal element can be formed of a flat sheet metal. Pre-machined sheet metal can be understood as a die-stamped, pre-cut and/or laser-cut sheet metal element. The pre-machined sheet metal can be configured in a one-piece design, such that the first electric terminal device, the control terminal, the second electric terminal device and/or the edge region of the terminal apparatus can be integrally formed. Prior to the bending step, the first electric terminal device, the control terminal, the second electric terminal device and/or the edge region can be arranged in a common plane. Alternatively, individual elements of the pre-machined sheet metal, for example the first electric terminal device and/or the path section, can be pre-bent. The edge region can be circumferentially arranged about the first electric terminal device, the control terminal and the second electric terminal device. For example, the edge region can be separated by a near-circumferential edge gap from the first electric terminal device, the control terminal and/or the second electric terminal device, and only connected by means of individual connecting webs to the first electric terminal device, the control terminal and/or the second electric terminal device. The electrical or electronic component can be a semiconductor component, for example a power semiconductor such as an insulated-gate bipolar transistor, or “IGBT” for short, and/or a diode. The electronic module can be a power module, for example of a power converter for an electric axle drive of a motor vehicle. The first terminal device is employed to connect the module/power module to the first electrical potential, which can be, for example, an electrical drain potential. The control contact can be a gate pin. The control terminal can also comprise a second control contact, for example in the form of a Kelvin-source pin. The first path can be an electrically conductive or current-conducting path for contact-connection with the terminal for the second electrical potential of the electrical or electronic component. The second path can likewise be an electrically conductive or current-conducting path. The second path can be a second path which is arranged in parallel with the first path. The second electrical potential can be a source potential, such that the terminal for the second electrical potential can be a source potential terminal. In the bending step, the edge region of the sheet metal can be bent, for example into a U-shape or bridge shape, such that the gap between the first electric terminal device and the path section is reduced, or even closed. By means of the message envisaged herein, a leadframe can be shortened, such that connecting elements at different potentials can assume a combined arrangement within the module in very close proximity.

In the bending step, a central track section of the edge region and/or a further central track section of the edge region arranged in opposition to said central track section can be bent in one direction, such that a length of the track section and/or of the further track section is reduced, by means of which the first electric terminal device and the path section are brought together. Thus, simply by bending the edge region which, for example, will be removed subsequently in any event, a desired positioning of the first electric terminal device and the path section can be achieved. The central track section and the further central track section can be arranged on two mutually averted sides of the circumferential track region.

The method can further comprise a die-stamping or laser cutting step, which precedes the bending step, in which a sheet metal blank is die-stamped or laser cut in order to obtain the pre-machined sheet metal element wherein, in the die-stamping and/or laser cutting step, the sheet metal blank is die-stamped or laser cut such that the gap between the first electric terminal device and the path section is generated. The sheet metal blank can be a flat, for example a rectangular sheet metal blank. By means of the gap, it can be ensured that no direct connection exists between the first electric terminal device and the second electric terminal device.

The method can moreover comprise a further bending step, in which the control contact is bent in one direction. In the further bending step, the second control contact can also be bent in a corresponding manner to the control contact. The control contact and/or the second control contact can be centrally bent, for example, through approximately 90 degrees. The control contacts can be bent transversely/perpendicularly to a main extension plane of the originally flat sheet metal blank.

It is further advantageous if the method, according to one embodiment, comprises an additional bending step, in which a first bending section of the first path is bent into a lower plane than a second bending section of the second path, or in which the second bending section is bent for contact-connection with a further terminal for the first potential of the electrical or electronic component, in a corresponding manner to the first bending section. The second path can be correspondingly formed, prior to the additional bending step for the first path. A “lower plane” is to be understood as lower bent plane in the bending direction. If, in the additional bending step, the first bending section of the first path is bent into a lower plane than the second bending section of the second path, the first path can advantageously be employed, further to the additional bending step, for contact-connection with the terminal for the second electrical potential of the electrical or electronic component, whereas the second path, further to the additional bending step, is not contact-connected with the terminal for the second electrical potential, but is arranged with a clearance to the terminal for the second electrical potential. If, alternatively, in the additional bending step, the second bending section is bent to a depth which corresponds to that of the first bending section, the second bending section can then be employed for contact-connection with the further terminal for the first electrical potential of the electrical or electronic component. Alternatively, if the first bending section is bent into a lower plane than the second bending section, a further first path of the path section, which is arranged in parallel with the first path, for contact-connection with a further terminal for the first potential of the electrical or electronic component, can also be bent in a corresponding manner to the first bending section. In the additional bending step, the first bending section, the second bending section and/or the further first path can be bent, for example, into a wave shape. The first electrical potential can be a drain potential, such that the further terminal for the first electrical potential can be a drain terminal. Thus, according to one embodiment, the path section, for example, comprises the first path for contact-connection with the second potential, the further first path for contact-connection with the first potential, and the second path, which is arranged with a clearance from both potential. Thus, in the leadframe, a parallel arrangement of current-conducting paths is permitted, which are partly connected to the semiconductor source potentials, and partly not. The parallel arrangement of current-conducting path permits parallel current conduction, without the connection of the power semiconductor. For the connection of the terminal/chip, the leadframe, on the upper side of the terminal/chip and/or of the further terminal, is bent downwards. In the region of the parallel paths, for example, an alternative form of bending is employed for the second bending section, which can correspond to the identical length from the bend leadframe to the chip. This alternative form which is executed, for example, as a wave shape, is selected such that the clearance to the electrical or electrical component, or to a circuit board such as a direct bonded copper substrate, or “DBC” for short, on which the component is arranged, permits the isolation of the leadframe from the component or from the direct bonded copper substrate.

In the additional bending step, the sheet metal can be bent such that it further comprises at least one second path section which is arranged between the first electric terminal device and the control terminal, which comprises a third path for contact-connection with a terminal for the second electrical potential of a second electrical or electronic component, and at least one fourth path which is arranged in parallel with the third path wherein, in the additional bending step, a third bending section of the third path is bent into a lower plane than a fourth bending section of the fourth path, or the third bending section and the fourth bending section are bent in a corresponding manner to the first bending section. The third path and/or fourth path can be configured in an electrically conductive or current-conducting manner. Thus, by means of the second path section, a second electrical or electronic component, which can also be a semiconductor component, can further be connected to the terminal apparatus. The third bending section can thus be shaped according to the first bending section, wherein the fourth bending section, as per the second bending section, is either not contact-connected with the second component, and is thus bent to a shorter depth, in accordance with the second bending section, or the fourth bending section, as per the further first bending section, can be shaped for contact-connection with a terminal for the first electrical potential of the second component.

According to one embodiment, in the additional bending step, the third bending section and the fourth bending section of the second path section can be bent, wherein the path section and the second path section are arranged adjacently to one another or one behind the other. Electrical or electronic components which are arranged adjacently, or one behind another, can be contact-connected accordingly.

A method for manufacturing an electrical or electronic module comprises a resourcing step and a contact-connection step. In the resourcing step, a terminal apparatus, which has been produced by the employment of the above-mentioned method in one of the above-mentioned variants, and the electrical or electronic component are provided. In the contact-connection step, a first bending section of the first path is contact-connected with a terminal for the second electrical potential of the electrical or electronic component, in order to produce the electrical or electronic module.

According to one embodiment, the method can further comprise a step for removing the edge region of the sheet metal blank or the pre-machined sheet metal element. In the removal step, for example, the edge region can be cut off, removed by laser cutting and/or stamped off.

The method can also comprise a fastening step, wherein the first bending section is soldered or sintered to the terminal for the second electrical potential of the electrical or electronic component and/or a further first bending section of the further first path is soldered or sintered to a further terminal for the first electrical potential of the electrical or electronic components, and/or at least one connecting section of the terminal apparatus can be soldered or sintered to a substrate which carries the electrical or electronic component, for example a direct bonded copper substrate, or to another circuit board. A stable fastening of the terminal apparatus to the terminals and/or to the substrate can thus be achieved.

The method can further comprise a molding step, wherein at least the path section and the electrical or electronic component which are contact-connected by the first bending section are over-molded. An additional protection and additional stabilization of the first bending section and/or of the electrical or electronic component can thus be achieved.

The method can also comprise a bonding step, wherein a gate terminal or the electrical or electronic component is directly or indirectly connected to the control contact and/or a signal terminal of the electrical or electronic component is directly or indirectly connected to the second control contact and/or a further signal terminal, which can be a Kelvin-source terminal, of the electrical or electronic component is directly or indirectly connected to the first electric terminal device, for example to the path section. In the bonding step, connections can be formed e.g. by means of bonding wires. An operational electrical or electronic module can thus be provided.

An electrical or electronic module comprises a substrate, which can be a direct bonded copper substrate or another circuit board, and at least one electrical or electronic component which is arranged on the substrate, and a terminal apparatus produced by a method according to one of the above-mentioned variants, wherein the first bending section of the first path is contact-connected with the terminal for the second electrical potential of the electrical or electronic component.

The approach envisaged herein further provides an apparatus which is configured to execute, actuate or implement the steps of a variant of the method presented herein in corresponding devices. By means of these variants of embodiment of the approach envisaged, in the form of an apparatus, the fundamental object of this approach can also be fulfilled in a rapid and efficient manner.

An apparatus can be an electrical device which processes electrical signals, for example sensor signals, and delivers an output of control signals in accordance therewith. The apparatus can comprise one or more interfaces, the configuration of which can be hardware-based and/or software-based. In a hardware-based embodiment, the interfaces can be, for example, an element of an integrated circuit in which functions of the apparatus are implemented. Interfaces can also be dedicated and integrated switching circuits, or can be at least partially comprised of discrete components. In a software-based embodiment, interfaces can be software modules which, for example, are present in a microcontroller, in addition to other software modules.

A computer program product is also advantageous, having program code which can be saved on a machine-readable medium, such as a semiconductor memory, a hard disk memory or an optical memory, and is employed for executing the method in one of the above-mentioned embodiments when the program is run on a computer or an apparatus.

The invention additionally relates to a power converter, particularly an inverter, for a motor vehicle, having a terminal apparatus produced by the employment of a method according to one of the above-mentioned variants. The power converter is characterized in that the terminal apparatus is configured in the manner described.

The power converter can be configured in the form of a power inverter or inverter. By the employment of a power converter, the requisite alternating current for the operation of the electrical machine can be delivered.

The invention further relates to an electric axle drive for a motor vehicle having at least one electrical machine, a transmission device, and an above-mentioned power converter, particularly an inverter. The electric axle drive is characterized in that the power converter is configured in the manner described above.

By the employment of the transmission device, a torque which is generated by the electrical machine is converted into a drive torque for driving at least one wheel of the motor vehicle. The transmission device can comprise a gearbox for stepping down the rotational speed of the electrical machine, and can optionally comprise a differential.

The invention additionally relates to a motor vehicle having an electric axle drive and/or a power converter. The motor vehicle is characterized in that the electric axle drive and/or the power converter are configured as per one of the above-mentioned variants.

Exemplary embodiments of the approach envisaged herein are represented in the drawings and described in further detail in the following description.

### BRIEF DESCRIPTION OF THE DRAWINGS

FIG. 1 shows a schematic representation of an exemplary embodiment of a motor vehicle;

FIG. 2 shows a schematic representation of an exemplary embodiment of a power converter for an electric axle drive of a motor vehicle;

FIG. 3 shows a schematic representation of an exemplary embodiment of a terminal apparatus for connecting at least one electrical or electronic component for an electrical or electronic module;

FIG. 4 shows a schematic view of an exemplary embodiment of a terminal apparatus;

FIG. 5 shows a perspective representation of a pre-machined sheet metal element for producing a terminal apparatus according to one exemplary embodiment;

FIG. 6 shows a perspective representation of a first bending section and a second bending section of pre-machined sheet metal element for producing a terminal apparatus according to one exemplary embodiment;

FIG. 7 shows a schematic view of an electrical or electronic module according to one exemplary embodiment;

FIG. 8 shows a lateral cross-sectional representation of a first bending section and a second bending section of an electrical or electronic module according to one exemplary embodiment;

FIG. 9 shows a schematic view of an electrical or electronic module according to one exemplary embodiment;

FIG. 10 shows a perspective view of different production stages during an exemplary production process of a terminal apparatus according to one exemplary embodiment, and an electrical or electronic module according to one exemplary embodiment;

FIG. 11 shows a perspective view of different production stages during an exemplary production process of a terminal apparatus according to one exemplary embodiment;

FIG. 12 shows a perspective representation of an electrical or electronic module according to one exemplary embodiment;

FIG. 13 shows a flow diagram of an exemplary embodiment of a method for manufacturing a terminal device for connecting at least one electrical or electronic component for an electrical or electronic module; and

FIG. 14 shows a flow diagram of an exemplary embodiment of a method for manufacturing an electrical or electronic module.

### DETAILED DESCRIPTION

In the following description of preferred exemplary embodiments of the approach presented herein, identical or similar reference numbers are employed for elements having a similar action which are represented in the various figures, wherein any repeated description of these elements is omitted.

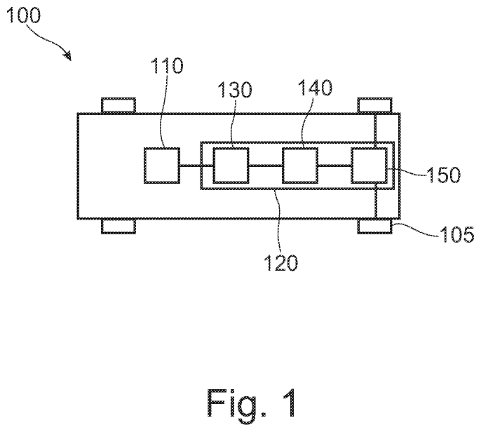

FIG. 1 shows a schematic representation of an exemplary embodiment of a motor vehicle 100. Of the motor vehicle 100 represented in FIG. 1, wheels 105, wherein four wheels 105 are represented by way of an example only, an electrical energy store 110, for example a battery, and an electric axle drive 120 are shown. The electric axle drive 120 comprises a power converter 130, an electrical machine 140 and a transmission device 150.

Electrical energy for operating the electrical machine 105 is delivered by an energy supply device, in this case the electrical energy 110. The electrical energy store 110 is configured to supply a direct current which, by the employment of a power converter 130 of the electric axle drive 120, is converted into an alternating current, for example a three-phase alternating current, and is delivered to the electrical machine 140. A shaft which is driven by the electrical machine 140 is coupled to at least one wheel 105 of the motor vehicle 100, either directly or via a transmission device 150. The motor vehicle 100 can thus be propelled by the employment of the electrical machine 140. According to one exemplary embodiment, the electric axle drive 120 comprises a housing in which the power converter 130, the electrical machine 140 and the transmission device 150 are arranged.

In particular, the power converter 130 and the components thereof are addressed in greater detail, with reference to the following figures.

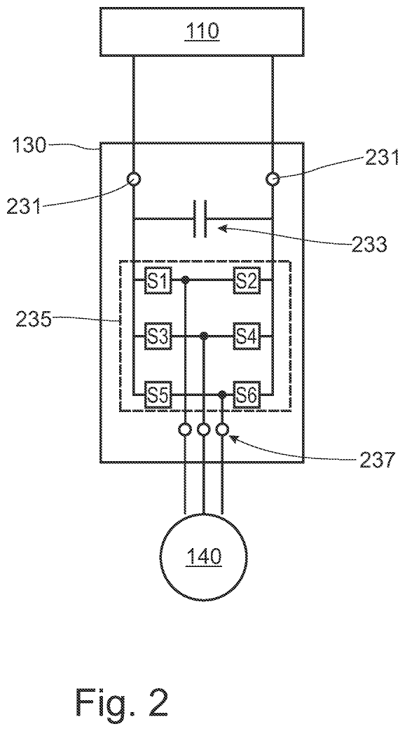

FIG. 2 shows a schematic representation of an exemplary embodiment of a power converter 130 for an electric axle drive of a motor vehicle. The power converter 130 corresponds or is similar to the power converter according to FIG. 1. For illustrative purposes, moreover, additionally to the power converter 130, the electrical energy store 110 and the electrical machine 140 of the electric axle drive are also represented in FIG. 2. The power converter 130 comprises DC terminals 231, a link capacitor 233, a plurality of power modules 235 and AC terminals 237.

The DC terminals 231 are provided for the delivery of a direct current from the electrical energy store 110 of the motor vehicle. In other words, the power converter 130 is connectable or connected, via the DC terminals 231, to the electrical energy store 110. The link capacitor 233 is electrically connected to the first of the DC terminals 231 and to the second of the DC terminals 231. The alternating current terminals 237 are provided for the delivery of an alternating electric current for the electrical machine 140 of the electric axle drive. In other words, the power converter 130 is connectable or connected, via the AC terminals 237, to the electrical machine 140. The DC terminals 231 and/or the AC terminals 237, for example, are formed to respectively accommodate one end of a power cable, and are mechanically and electrically contact-connected, for example by screwing, clamping or soldering.

The power modules 235 comprise switching devices, and are designed to convert direct current into alternating current. The power modules 235, which are also described hereinafter as electrical or electronic modules, will now be addressed in greater with reference to the following figures. According to the exemplary embodiment represented here, the power converter 130, for exemplary purposes only, comprises six power modules 235, in this case a first power module S1, a second power module S2, a third power module S3, a fourth power module S4, a fifth power module S5 and a sixth power module S6. The power modules 235 or S1, S2, S3, S4, S5 and S6 are interconnected in a B6 bridge circuit. A first of the DC terminals 231 is electrically connected to a first terminal of the first power module S1, to a first terminal of the third power module S3, and to a first terminal of the sixth power module S5. A second of the DC terminals 231 is electrically connected to a first terminal of the second power module S2, to a first terminal of the fourth power module S4, and to a first terminal of the sixth power module S6. A first of the AC terminals 237 is electrically connected to a second terminal of the first power module S1 and to a second terminal of the second power module S2. A second of the AC terminals 237 is electrically connected to a second terminal of the third power module S3 and to a second terminal of the fourth power module S4. A third of the AC terminals 237 is electrically connected to a second terminal of the fifth power module S5 and to a second terminal of the sixth power module S6.

According to one exemplary embodiment, the power converter 130 can be operated in a reverse direction, such that the electrical machine 140 can be employed as a generator for charging the electrical energy store 110.

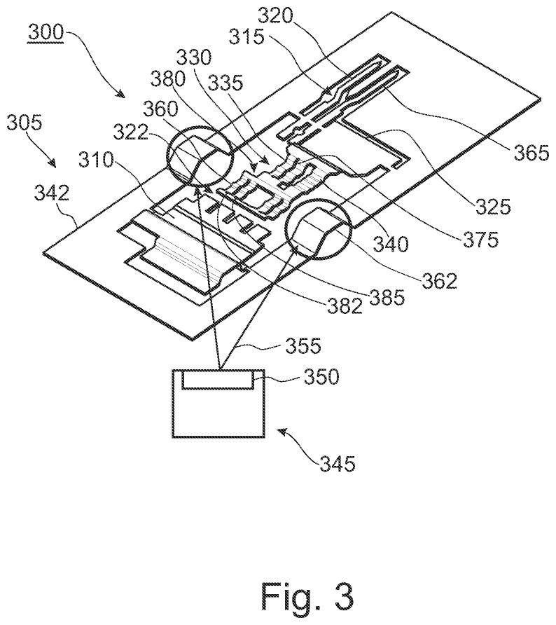

FIG. 3 shows a schematic representation of an exemplary embodiment of a terminal apparatus 300 for connecting at least one electrical or electronic component for an electrical or electronic module.

According to one exemplary embodiment, the electrical or electronic module is one of the power modules described in FIG. 2, which is suitable for use with the power converter described in FIG. 1 or 2 for the electric axle drive described in FIG. 1 or 2 of the motor vehicle described in FIG. 1 or 2.

The terminal apparatus 300 comprises a pre-machined sheet metal element 305 having a first electric terminal device 310 for connecting to a first electrical potential, a control terminal 315 having at least one control contact 320, and a second electric terminal device 325 which is arranged between the first electric terminal device 310 and the control terminal 315 and is separated from the first electric terminal device 310 by a gap 322, for connecting to a second electrical potential, wherein the second electric terminal device 325 has a path section 330 which comprises a first path 335 for contact-connection with a terminal for the second electrical potential of the electrical or electronic component, and at least one second path 340 which is arranged in parallel with the first path 335. An edge region 342 of the sheet metal 305 is bent such that the first electric terminal device 310 and the path section 330 are brought together, such that the first electric terminal device 310 and the path section 330 are arranged with an overlap. According to this exemplary embodiment, the first electric terminal device 310 is not directly contact-connected with the path section 330, notwithstanding the overlap. According to an alternative exemplary embodiment, the first electric terminal device 310 is directly contact-connected with the path section 330, on the grounds of the overlap.

FIG. 3 further shows an apparatus 345 which designed to execute and/or actuate the manufacture of the terminal apparatus 300. To this end, the apparatus 345 comprises an output device 350, which is configured to generate an output of a bending signal 355 in order to execute a bending of the edge region 342, such that the first electric terminal device 310 and the path section 330, as represented here, are brought together, such that the first electric terminal device 310 and the path section 330 are arranged with an overlap.

According to this exemplary embodiment, the output device 350 is configured to generate an output of the bending signal 355 which is designed to execute the bending of a track section 360 of the edge region 342 and/or of a further central track section 362 of the edge region 342 which is arranged opposite said track section 360, in order to reduce a length of the track section 360 and/or of the further track section 362, such that the first electric terminal device 310 and the path section 330 are brought together. FIG. 3 represents an outcome for the achievement of the bent states of the track sections 360, 362 of the edge region 342 executed by the bending signal 355.

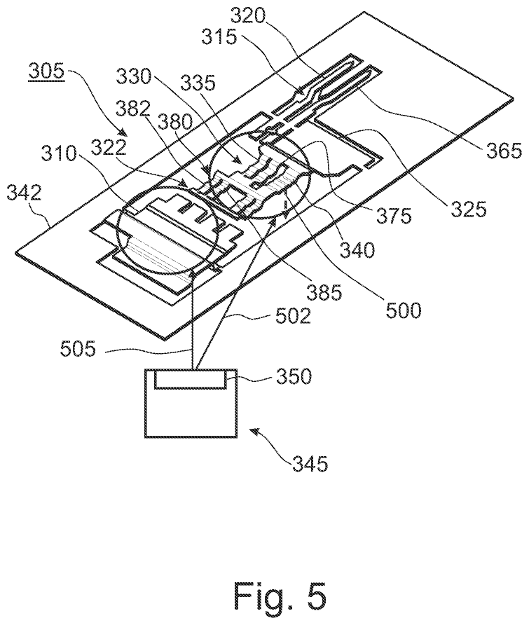

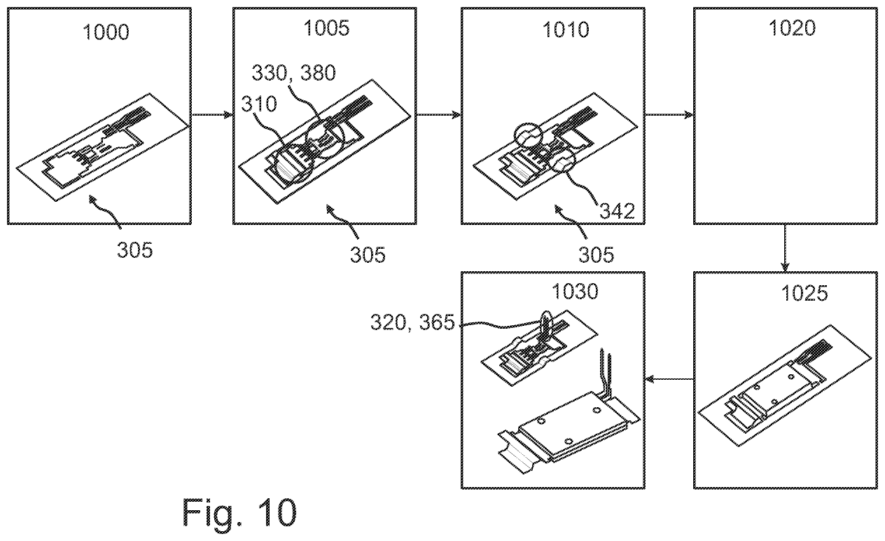

According to this exemplary embodiment, the terminal apparatus 300 is configured in the form of a “leadframe”, i.e. as a metallic connecting frame. The pre-machined sheet metal element 305, according to the present exemplary embodiment, is an originally flat sheet metal element wherein, according to the present exemplary embodiment, in an optional manner only, the first electric terminal device 310 and/or the path section 330 have been pre-bent—see FIG. 5. The pre-machined sheet metal element 205 according to the present exemplary embodiment has been die-stamped, cut-out and/or laser-cut to form the first electric terminal device 310, the control terminal 315, the second electric terminal device 325 and the edge region 342. According to the present exemplary embodiment, the pre-machined sheet metal element 205 is configured in a one-piece design, such that the first electric terminal device 310, the control terminal 315, the second electric terminal device 325 and/or the edge region 342 of the terminal apparatus 300 are formed in a mutually integral manner. Prior to the output of the bending signal 355, which generates the bent state of the track sections 360, 362 of the edge region 342 represented here, the entire edge region 342 was arranged in a common plane—c.f. FIG. 5 or 10. In an optional manner only, according to the present exemplary embodiment, the first electric terminal device 310 and/or the path section 300 are represented in a bent state, wherein a bending process of the first electric terminal device 310 and/or the path section 330 is described in greater detail in FIG. 5.

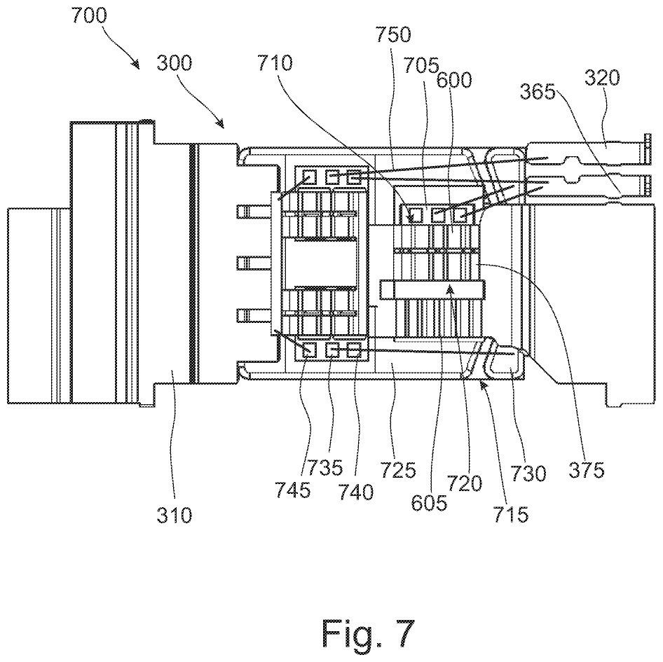

According to the present exemplary embodiment, the first terminal device 310 is employed for connecting the module/power module to the first electrical potential, which is configured, for example, as an electrical drain potential. According to the present exemplary embodiment, the control contact 320 is configured as a gate pin. According to the present exemplary embodiment, the control terminal 315 also comprises a second control contact 365, which is configured here, for exemplary purposes, as a Kelvin-source pin. According to the present exemplary embodiment, the first path 335 is configured as an electrically conductive or current-conducting path, and is employed for contact-connection with the terminal for the second electrical potential of the electrical or electronic component—see FIG. 7. According to the present exemplary embodiment, the second path 340 is also configured as an electrically conducting or current-conducting path wherein, according to the present exemplary embodiment, the second path 340 is not configured for the contact-connection of a terminal for an electrical potential of the electrical or electronic component. According to the present exemplary embodiment, the second path 340 is a second path 340 which is arranged in parallel with the first path 335. A first bending section of the first path 330, according to the present exemplary embodiment, is bent into a lower plane than a second bending section of the second path 340. The term “deeper plane” is to be understood as a plane which is bent deeper in the bending direction. Given that, according to the present exemplary embodiment, the first bending section of the first path 335 is bent into a deeper plane than the second bending section of the second path 340, the first path 335 can advantageously be employed for contact connection with the terminal for the second electrical potential of the electrical or electronic component, whereas the second path 340 does not contact-connect the terminal for the second electrical potential, but is arranged with a clearance to the terminal for the second electrical potential. According to the present exemplary embodiment, the second electrical potential is configured as a source potential, such that the terminal for the second electrical potential, according to the present exemplary embodiment, is a source potential terminal.

The path section 330 of the terminal apparatus 300, according to the present exemplary embodiment, additionally comprises a further first path 375, which is arranged in parallel with the first path 335, wherein the further first path, according to the present exemplary embodiment, is bent for contact-connection with a further terminal for the first potential of the electrical or electronic component, in a corresponding manner to the first bending section. According to the present exemplary embodiment, the further first path 375 is also an electrically conductive or current-conducting path. The first electrical potential can be a drain potential, such that the further terminal for the first electrical potential can be a drain terminal.

According to the present exemplary embodiment, the pre-machined sheet metal element 305 further comprises at least one second path section 380, which is arranged between the first electric terminal device 310 and the control terminal 315, and which comprises a third path 382 for contact-connection with a terminal for the second electrical potential of a second electrical or electronic component, and at least one fourth path 385 which is arranged in parallel with the third path 382 wherein, according to the present exemplary embodiment, a third bending section of the third path 382 and a fourth bending section of the fourth path 385 are bent in a corresponding manner to the first bending section or, according to an alternative exemplary embodiment, the third bending section of the third path 382 is bent into a lower plane than the fourth bending section of the fourth path 385. According to this exemplary embodiment, the third path 382 and/or the fourth path 385 are also configured as electrically conductive or current-conducting. According to one exemplary embodiment, the third path 382 and/or the fourth path 385 are also bent in response to the bending signal 255.

According to this exemplary embodiment, the path section 330 and the second path section 380 are arranged with an offset, one behind the other. According to an alternative exemplary embodiment, the path section 330 and the second path section 380 are arranged adjacently to one another, or are configured in a flush arrangement, one behind the other. According to this exemplary embodiment, the path section 330 is arranged to face the control terminal 315, whereas the second path section 380 is arranged to face the first electric terminal device 310.

According to the present exemplary embodiment, the pre-machined sheet metal element 305 further comprises at least one third path section, which is arranged between the first electric terminal device 310 and the control terminal 315, and which comprises a fifth path for contact-connection with a terminal for the second electrical potential of an electrical or electronic component, and at least one sixth path which is arranged in parallel with the fifth path wherein, according to this exemplary embodiment, a fifth bending section of the fifth path and a sixth bending section of the sixth path are bent in a manner which corresponds to the first bending section or, according to an alternative exemplary embodiment, the fifth bending section of the fifth path is bent into a lower plane than the sixth bending section of the sixth path. According to this exemplary embodiment, the fifth path and/or the sixth path are also configured as electrically conductive or current-conducting. According to this exemplary embodiment, the second path section 380 and the third path section are arranged adjacently to one another, such that the third path 382, the fourth path 385, the fifth path and the sixth path are oriented in parallel.

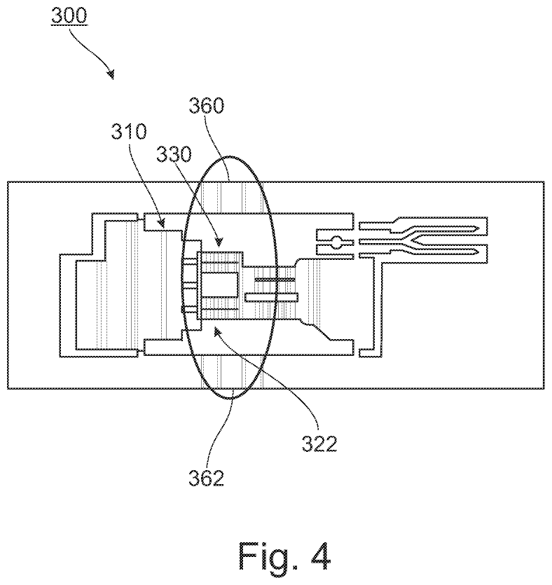

FIG. 4 shows a schematic view of one exemplary embodiment of a terminal apparatus 300. This can be the terminal apparatus 300 described in FIG. 3.

In the overhead view represented here, it can be seen that the electric terminal device 310 and the path section 330 are arranged with an overlap such that, in the overhead view, a gap 322 between the electric terminal device 310 and the path section 330 is no longer visible. According to this exemplary embodiment, however, the gap 322 is still present, in a plane which is not visible here and which is oriented in the image plane between the terminal device 310 and the path section 330. According to this exemplary embodiment, the electric terminal device 310 and the path section 330 are not contact-connected in the overlap region. According to an alternative exemplary embodiment, the electric terminal device 310 and the path section 330 are contact-connected in the overlap region.

FIG. 5 shows a perspective representation of a pre-machined sheet metal element 305 for manufacturing a terminal apparatus, according to one exemplary embodiment. This can be the sheet metal element 305 described in FIG. 3 or 4, but prior to the processing thereof by bending signal in order to produce the terminal apparatus.

As described above with respect to FIG. 3, the first bending section of the first path 330, according to this exemplary embodiment, is bent into a lower plane than the second bending section of the second path 340. The bending direction 500 of the paths 335, 340, 382, 385 described in FIG. 3 is further represented in FIG. 5.

In an optional manner only, the apparatus 345 according to the present exemplary embodiment is further configured, prior to the output of the bending signal described in FIG. 3, to generate the output of a first sheet metal bending signal 502 and/or a second sheet metal bending signal 505, wherein the first sheet metal bending signal 502 initiates the execution of a bending of the path section 330 represented here, and the second sheet metal bending signal 505 initiates the execution of a bending of the first electric terminal device 310. Prior to the output of the first sheet metal bending signal 502 and/or the second sheet metal bending signal 505, the first electric terminal device 310 and/or the path section 330, according to one exemplary embodiment, are arranged in a common flat plane with the edge region 342—see FIG. 10.

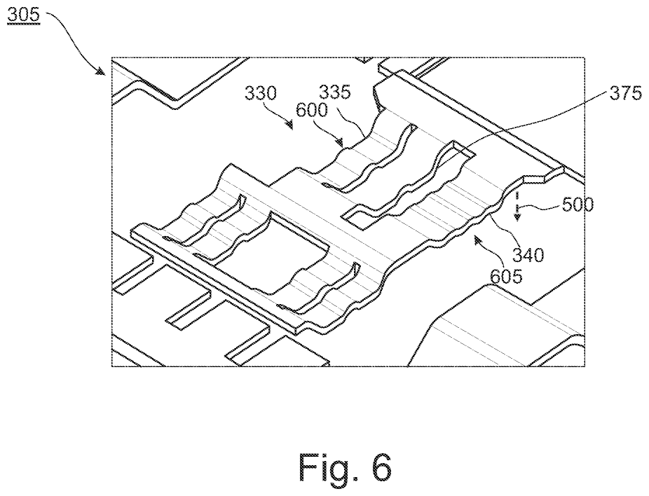

FIG. 6 shows a perspective representation of a first bending section 600 and a second bending section 605 of a pre-machined sheet metal element 305 for manufacturing a terminal apparatus, according to one exemplary embodiment. This can be the pre-machined sheet metal element 305 described in FIG. 5.

According to this exemplary embodiment, the first bending section 600 and/or the second bending section 605 are bent into a wave shape. The first bending section 600, for example along a length of the first bending section 600, is bent into at least two wave-shaped bends and/or the second bending section 605, along a length of the second bending section 605, is bent into at least four wave-shaped bends.

FIG. 6 shows a detailed view of the parallel-arranged current-conducting paths 335, 340, 375.

The parallel arrangement of current-conducting paths 335, 340, 375 permits a parallel routing of current, without the connection of a power semiconductor. For the connection of a terminal/chip, it is necessary for the leadframe to be bent down onto the upper side of the chip. In the region of the parallel paths 335, 375, for the second path 340, an alternative form of bending is executed wherein, according to this exemplary embodiment, the identical length of the bent leadframe corresponds to the chip. This alternative form, which is executed here in a wave shape, by way of an example, is selected such that the clearance to a circuit board, for example to a DBC board, permits an isolation of the leadframe vis-à-vis the DBC board.

FIG. 7 shows a schematic view of an electrical or electronic module 700, according to one exemplary embodiment. The electrical or electronic module 700 comprises a terminal apparatus 300 and an electrical or electronic component 705. These can be the terminal apparatus 300 described in FIG. 3 or 4 and the electrical or electronic component 705 described in FIG. 3 or 4. Conversely to the terminal apparatus 300 described in FIG. 3 or 4, according to this exemplary embodiment, the edge region has been removed from the sheet metal blank of the terminal apparatus 300.

According to this exemplary embodiment, the electrical or electronic module 700 is configured as a power module for an electric axle drive of a motor vehicle.

The first bending section 600 is contact-connected with the terminal 710 for the second electrical potential of the electrical or electronic component 705. In FIG. 7, the terminal 710 is covered by the first path. According to this exemplary embodiment, the second bending section 605 is arranged with a clearance to the terminal 710 for the second electrical potential and/or with a clearance to a further terminal 720 for the first potential of the electrical or electronic component 705.

According to this exemplary embodiment, the electrical or electronic module 700 further comprises a substrate 715, on which the electrical or electronic component 705 is arranged. According to this exemplary embodiment, the substrate 715 comprises a first electrical contact section 725 and a second electrical contact section 730, wherein the contact sections 725, 730 are electrically isolated from one another. According to this exemplary embodiment, the module 700 further comprises a plurality of electrical or electronic components 705 which are arranged on the substrate 715 and which, according to this exemplary embodiment, are respectively configured as semiconductor components, each having a terminal 710 for the second electrical potential, a further terminal 720 for the first electrical potential, a gate terminal 735, a signal terminal 740 and/or a further signal terminal 745, wherein the terminals 710 for the second electrical potential of all components 705 are electrically connected to the first contact section 725. The first electric terminal device 310, according to this exemplary embodiment, is electrically connected to the first contact section 725, and the second electric terminal device 325, according to this exemplary embodiment, is electrically connected to further terminals 720 for the first electrical potential of all the components 705. According to this exemplary embodiment, each of the path sections is respectively arranged above one of the components 705. The first control contact 320 is electrically connected to the gate terminals 735 of all the components 705, and the second control contact 365 is electrically connected to the signal terminals 740 of all the components 705. According to this exemplary embodiment, the further signal terminals 745 which, according to this exemplary embodiment, are Kelvin-source terminals, are directly or indirectly connected to the first electric terminal device 310. The connections are formed, for example, by means of bonding wires 750. According to an alternative exemplary embodiment, the electrical or electronic component 705 is configured as an insulated-gate bipolar transistor, or “IGBT” for short, and/or as a diode, and/or as a single-pole component, such as a MOSFET.

A first section length of the first bending section 600 and/or a second section length of the second bending section 605, according to the present exemplary embodiment, essentially correspond to a first component length of the electrical or electronic component 705.

The first bending section 600, according to this exemplary embodiment, is soldered or sintered to the terminal 710 for the second electrical potential of the electrical or electronic component 705 and/or the further first bending section of the further first path 375 is soldered or sintered to the further terminal 720 for the first electrical potential of the electrical or electronic component 705 and/or, according to one exemplary embodiment, at least one connecting section of the terminal apparatus is soldered or sintered to the substrate 715, which is configured here, for exemplary purposes, as a direct bonded copper substrate or, alternatively, as another circuit board.

The terminal apparatus 300 envisaged here advantageously permits an internal contact-connection of a power semiconductor assembly.

The terminal apparatus 300 envisaged here is employable in conjunction with all inverter systems, including entry-, mid- and high-platform systems, Formula E, 8-speed automatic transmissions, and charging devices for vehicle batteries—“on-board chargers”- or DC/DC converters.

A module based upon a leadframe design poses a challenge, in that all the terminals are formed from flat sheet metal. Forming operations in the third dimension, in order to provide e.g. insulating clearances or different connection heights for components will, by definition, result in greater clearances vis-à-vis the flat sheet metal. A restrictive design of this type results in minimum clearances between structures and semiconductors, which cannot be selected in consideration of thermal and electrical factors only, such that a module must be constructed to larger dimensions than necessary, or corresponding design compromises must be addressed, including specific semiconductor arrangements or power restrictions.

An electrical or electronic module 700, which can also be described as a “power module”, is therefore envisaged which:
in the leadframe (“connecting frame”), permits a parallel arrangement of current-conducting paths, which are partly connected to semiconductor source potentials and partly not,
permits an asymmetrical chip distribution in the package,
permits a connection of all the gate terminals 735 to the control contact 320 which, according to the present exemplary embodiment, is a gate pin,
has a common connecting substrate 715, in this case a DBC (direct bonded copper) structure, which maintains an optimum mutual thermal clearance between all the semiconductors,
permits optimum heat evacuation by means of the DBC board, and
according to one exemplary embodiment, comprises a “mold compound” which protects semiconductors from external influences, provides electrical insulation and transmits the requisite forces for a sintering process—see FIG. 10.

The optimum positioning of electrical or electronic components 705, for example in the form of semiconductors, on a circuit board, for example a “DBC” board, is based upon minimal thermal resistance. The connection of semiconductors, according to one exemplary embodiment, is achieved by means of a sintered or soldered connection. According to one exemplary embodiment, the combination of the leadframe and chips has been formed by means of a sintered or soldered connection. According to one exemplary embodiment, connection of the power-drain terminal to the DBC board has been executed by means of a welded, sintered and/or soldered connection. The same applies, in an analogous manner, to the emitter terminal of an IGBT, the anode of a diode, or the MOSFET terminal. Connection to the gate and Kelvin-source (Kelvin-emitter) pins 320, 365 is executed by means of bonding wires 750.

Gate terminals 735 have been routed via islands in the right-hand region of the DBC board, whereas Kelvin-source terminals 740 for the upper semiconductors are led directly to the Kelvin-source pin 365. The lower, in this case the third semiconductor, according to one exemplary embodiment, is contact-connected from the upper left-hand semiconductor via the power-source clip by means of additional bonding wires. Alternatively, according to one exemplary embodiment, the power-source clip is employed wherein, as a result of the load path in the clip, greater corruptions of potential can occur than in the variant having additional bonding wires to the Kelvin-source islands on the semiconductor.

The substrate 715/DBC, according to this exemplary embodiment, is formed of an insulating ceramic having the highest possible thermal conductivity, e.g. silicon nitride, or “SiN” for short, aluminum oxide, or “Al2O3” for short, or aluminum nitride, or “AlN” for short, coated on the upper side and/or underside with copper. The underside, according to one exemplary embodiment, is coated e.g. with silver, for a sintered or soldered connection.

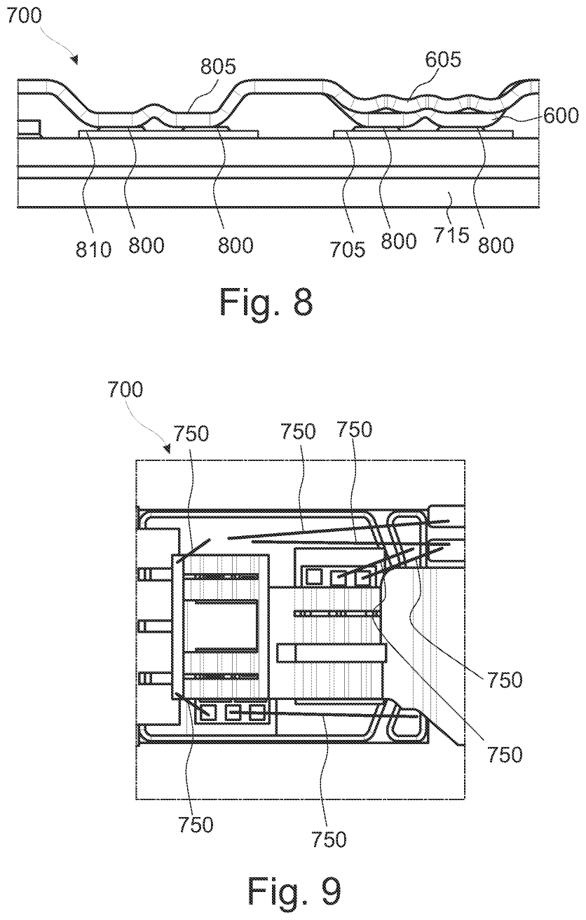

FIG. 8 shows a lateral cross-sectional view of a first bending section 600 and a second bending section 605 of an electrical or electronic module 700 according to one exemplary embodiment. This can be the module 700 described in FIG. 7.

According to one exemplary embodiment, a mechanical connection of the electrical or electronic component 705/semiconductor to the first bending section 600 and the further first bending section is formed, in each case, by one or more sintered or soldered connections 800. According to this exemplary embodiment, the second electrical or electronic component/semiconductor is also mechanically connected to the third and fourth bending sections, in each case, by means of one or more sintered or soldered connections 800. According to this exemplary embodiment, the third electrical or electronic component 810/semiconductor is also mechanically connected to the fifth and sixth bending sections 805, in each case, by means of one or more sintered or soldered connections 800. The second bending section 605, by means of a gap between the second bending section 605 and the component 705, is configured in an isolated arrangement from the component 705. According to this exemplary embodiment, a length of the second bending section 605 corresponds to a length of the first bending section 600.

FIG. 9 shows a schematic view of an electrical or electronic module 700 according to one exemplary embodiment. This can be the module 700 described in FIG. 7 or 8.

FIG. 9 shows a view of the bonding wires 750 in the module 700.

FIG. 10 shows a perspective view of different production stages during an exemplary manufacturing process of a terminal apparatus 300, according to one exemplary embodiment, and of an electrical or electronic module according to one exemplary embodiment. These can be a terminal apparatus 300 described in FIG. 3 or 4, and an electric or electronic module described in one of FIGS. 7 to 9.

In the manufacturing process for the terminal apparatus 300/leadframe envisaged here, firstly, from a sheet metal blank, contacts, in this case the first electric terminal device, the control terminal, the second electric terminal device and the edge section have been generated, for example cut-out/stamped-out by means of a die-stamping process 1000, in order to obtain the pre-machined sheet metal element 305. In a following optional first bending process 1005, according to this exemplary embodiment, optionally, a number of contacts, in this case specifically all the path sections 330, 380 and the first electric terminal device 310 have been bent for the purposes of contact-connection. In a following second bending process 1010, the leadframe, by means of bending or rejoining in the edge region 342 of the sheet metal, has been shortened, such that a minimization of clearances for the contact-connection/overlapping of the first electric terminal device 310 with the second electric terminal device is permitted, in order to produce the terminal apparatus 300. In a following optional sintering and/or soldering process 1020, the leadframe has been sintered/soldered to the DBC board and the semiconductors, in order to produce the module. Optionally, the module has then been over-molded in a molding process 1025. In a following optional third bending process 1030, the control contacts 320, 365 have been bent and/or a residual frame of the leadframe, which incorporates the edge region 342, has been removed by cutting/stamping.

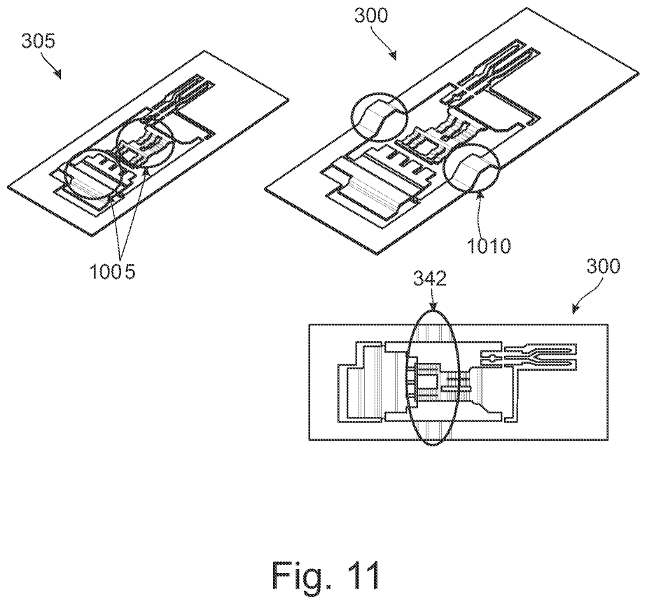

FIG. 11 shows a perspective view of different production stages during an exemplary manufacturing process of a terminal apparatus 300 according to one exemplary embodiment. Depending upon the outcomes, this can involve the first bending process 1005 and the second bending process 1010 described in FIG. 10.

In an optional first bending process 1005, the “drain” and “power source” terminals are bent.

The second bending process 1010 advantageously permits a shortening of the leadframe, such that connecting elements at different potentials, in this case the first electric terminal device and the second electric terminal device, can be combined in closer proximity within the module than in existing systems. In other words, in the second bending process 1010, two mutually opposing outer regions, in this case the edge regions 342 of the sheet metal are bent, such that the “drain” and “power source” can be configured in an overlapping arrangement.

According to one exemplary embodiment, die-stamping is executed by means of two or more than two individual processes, in order to achieve more complex geometries. Alternatively, the control contacts 320, 365 (gate/Kelvin-source), according to an alternative exemplary embodiment, are previously bent upwards in a first bending process 1005 or second bending process 1010 in the process chain, rather than in the final step of the process. The first bending process 1005 and the second bending process 1010, according to one exemplary embodiment, are executed in sequential process steps, either in different installations or in the same installation.

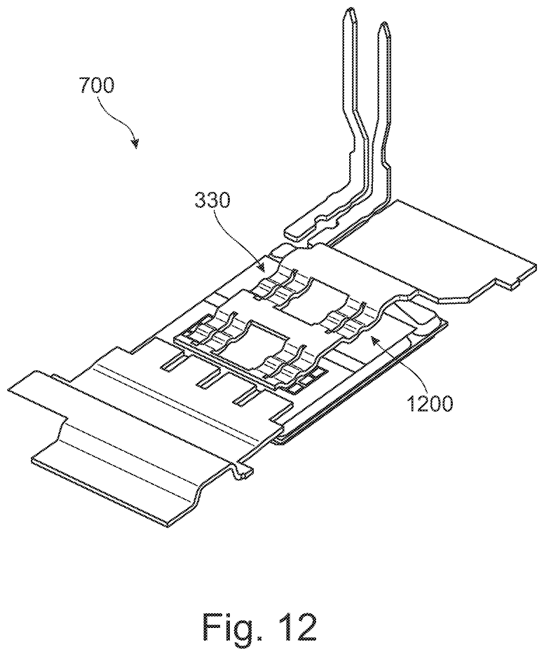

In addition to the embodiment of a 3-chip design represented here, according to different exemplary embodiment, other chip numbers are possible and, correspondingly, more bent path sections are formed on the second electric terminal device. For example, according to an alternative exemplary embodiment, the leadframe layout is configured for a 4-chip design—see FIG. 12.

FIG. 12 shows a perspective representation of an electrical or electronic module 700 according to one exemplary embodiment. This can be the module 700 described in FIG. 7, with the distinction that the terminal apparatus, according to this exemplary embodiment further comprises a fourth path section 1200, and the second bending section of the first path section 330 is bent in a corresponding manner to the first bending section for contact-connection with the further terminal for the first potential of the electrical or electronic component. According to this exemplary embodiment, it is also possible for the path section 330 to comprise no further first path. The fourth path section 1200, according to this exemplary embodiment, is arranged adjacently to the path section 330, such that the first path, the second path, a seventh path of the fourth path section 1200 and an eighth path of the fourth path section 1200 are configured in a parallel and identical manner. According to this exemplary embodiment, the first path is arranged flush to the third path, the second path is arranged flush to the fourth path, the fifth path is arranged flush to the seventh path, and the sixth path is arranged flush to the eighth path.

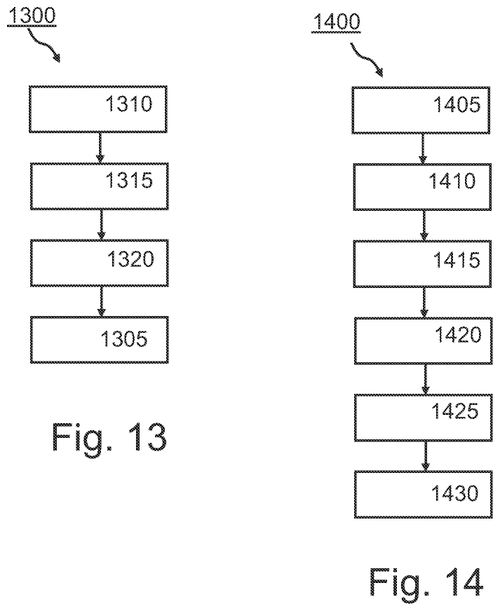

FIG. 13 shows a flow diagram of an exemplary embodiment of a method 1300 for manufacturing a terminal apparatus for connecting at least one electrical or electronic component for an electrical or electronic module. This can be one of the terminal apparatuses described with reference to one of FIGS. 3 to 4 or 7 to 12.

The method 1300 comprises a bending step 1305. In the bending step 1305, a pre-machined sheet metal element is bent, such that a first electric terminal device for connecting to a first electrical potential, a control terminal having at least one control contact, and a second electric terminal device for connecting to a second electrical potential, which is arranged between the first electric terminal device and the control terminal, and is separated from the first electric terminal device by a gap, are provided, wherein the second electric terminal device has a path section which comprises a first path for contact-connection with a terminal for the second electrical potential of the electrical or electronic component, and at least one second path, which is oriented in parallel with the first path. In the bending step 1310, an edge region of sheet metal is bent such that the first electric terminal device and the path section are brought together, wherein the terminal apparatus is formed by an overlapping arrangement of the first electric terminal device and the path section.

The bending step 1305 can correspond to the second bending process described in FIG. 10 or 11.

According to this exemplary embodiment, the method 1300 comprises, in an optional manner only, a die-stamping and/or laser cutting step 1310, a further bending step 1315 and/or an additional bending step 1320.

In the die-stamping and/or laser cutting step 1310, prior to the bending step 1305, a sheet metal blank is die-stamped or laser cut in order to obtain the pre-machined sheet element wherein, in the die-stamping and/or laser cutting step 1310, the sheet metal blank is die-stamped or laser cut such that a gap is formed between the first electric terminal device and the path section.

In the further bending step 1315, prior to or after the bending step 1305, the control contact is bent in one direction. In the further bending step 1315, the second control contact can also be bent in a corresponding manner to the control contact.

In the additional bending step 1320, prior to or after the bending step 1305, a first bending section of the first path is bent into a lower plane than a second bending section of the second path, or the second bending section, for contact connection with a further terminal for the first potential of the electrical or electronic component, is bent in a corresponding manner to the first bending section.

FIG. 14 shows a flow diagram of an exemplary embodiment of a method 1400 for manufacturing an electrical or electronic module. This can be an electrical or electronic module described with reference to one of FIGS. 7 to 12.

The method 1400 comprises a resourcing step 1405 and a contact-connection step 1410. In the resourcing step 1405, a terminal apparatus, which has been produced by the employment of the method described in FIG. 13, and the electrical or electronic component are provided. In the contact-connection step 1410, a first bending section of the first path is contact-connected with a terminal for the second electrical potential of the electrical or electronic component, in order to produce the electrical or electronic module.

According to one exemplary embodiment 1400, the method further comprises a fastening step 1415, a molding step 1420, a further bending step 1425 and/or a removal step 1430.

In the fastening step 1415, the first bending section is soldered or sintered to the terminal for the second electrical potential of the electrical or electronic component and/or a further first bending section of the first path section is soldered or sintered to a terminal for the first electrical potential of the electrical or electronic component, and/or at least one connecting section of the terminal apparatus is soldered or sintered to a substrate which carries the electrical or electronic component, for example a direct bonded copper substrate, or to another circuit board. In the molding step 1420, at least the path section and the electrical or electronic component which is contact-connected by the first bending section are over-molded. In the further bending step 1425, the control contact is bent in one direction. In the further bending step 1425, according to one exemplary embodiment, a second control contact is also bent in a corresponding manner to the control contact. In the removal step 1430, an edge region of the sheet metal blank or the pre-machined sheet metal element is removed. For example, in the removal step 1430, the edge region is removed by cutting, laser cutting and/or stamping.

The exemplary embodiments described and represented in the figures have been selected for exemplary purposes only. Different exemplary embodiments can be mutually combined, either in their entirety or with respect to individual features. An exemplary embodiment can also be expanded to include the features of a further exemplary embodiment.

Moreover, the process steps envisaged herein can be repeated, or can be executed in a sequence other than that described.

Where an exemplary embodiment of an “and/or” association between a first feature and a second feature, it is to be understood that the exemplary embodiment, according to one embodiment, comprises both the first and the second feature and, according to another embodiment, comprises only the first feature or the second feature.

### REFERENCE NUMBERS

100 Motor vehicle
105 Wheels
110 Electrical energy store
120 Electric axle drive
130 Power converter
140 Electrical machine
150 Transmission device
231 DC terminals
233 Link capacitor
235 Power modules
237 AC terminals
S1 First power module
S2 Second power module
S3 Third power module
S4 Fourth power module
S5 Fifth power module
S6 Sixth power module
300 Terminal apparatus
305 Pre-machined sheet metal element
310 First electric terminal device
315 Control terminal
320 Control contact
322 Gap
325 Second electric terminal device
330 Path section
335 First path
340 Second path
342 Edge region
345 Apparatus for manufacturing a terminal apparatus
350 Output device
355 Bending signal
360 Central track section
362 Opposing central track section
365 Second control contact
375 Further first path
380 Second path section
382 Third path
385 Fourth path
500 Bending direction
502 First sheet metal bending signal
505 Second sheet metal bending signal
600 First bending section
605 Second bending section
700 Electrical or electronic module
705 Electrical or electronic component
710 Terminal for the second electrical potential of the electrical or electronic
component
715 Substrate
720 Further terminal for the first potential of the electrical or electronic component
725 First electrical contact section
730 Second electrical contact section
735 Gate-Anschluss
740 Signal terminal
745 Further signal terminal
750 Bonding wire
800 Sintered or soldered connection
805 Sixth bending section
810 Third electrical or electronic component
1000 Die-stamping process
1005 First bending process
1010 Second bending process
1020 Sintering and/or soldering process
1025 Molding process
1030 Third bending process
1200 Fourth path section
1300 Method for manufacturing a terminal apparatus
1305 Bending step
1310 Die-stamping and/or laser cutting step
1315 Further bending step
1320 Additional bending step
1400 Method for manufacturing an electrical or electronic module
1405 Resourcing step
1410 Contact-connection step
1415 Fastening step
1420 Molding step
1425 Further bending step
1430 Removal step

1. A method of manufacturing a terminal apparatus for connecting at least one electrical or electronic component for an electrical or electronic module, the method comprising:
bending a pre-machined sheet metal element comprising:
a first electric terminal device configured to connect to a first electrical potential;
a control terminal having at least one control contact; and
a second electric terminal device arranged between the first electric terminal device and the control terminal and separated from the first electric terminal device by a gap, wherein the second electric terminal device is configured to connect to a second electrical potential,
wherein the second electric terminal device has a path section which comprises a first path for contact-connection with a terminal for the second electrical potential of the electrical or electronic component, and/or at least one second path which is arranged in parallel with the first path, and
wherein the bending includes bending an edge region of the sheet metal such that the first electric terminal device and the path section are brought together, such that the first electric terminal device and the path section are arranged with an overlap.

2. The method according to claim 1, comprising:
bending in a direction a central track section of the edge region and/or a further central track section of the edge region arranged in opposition to said track section such that a length of the track section and/or of the further track section is reduced, wherein the first electric terminal device and the path section are brought together.

3. The method according to claim 1, comprising:
prior to bending, die-stamping and or laser-cutting a sheet metal blank to obtain the pre-machined sheet metal element such that the gap between the first electric terminal device and the path section is generated.

4. The method according to claim 1, comprising:
bending the control contact in one direction.

5. The method according to claim 1, comprising:
bending a first bending section of the first path into a lower plane than a second bending section of the second path, or wherein the second bending section is bent for contact-connection with a further terminal for the first potential of the electrical or electronic component, in a corresponding manner to the first bending section (600).

6. The method according to claim 5, comprising:
bending the pre-machined sheet metal element such that it further comprises at least one second path section which is arranged between the first electric terminal device and the control terminal, which comprises a third path for contact-connection with a terminal for the second electrical potential of a second electrical or electronic component, and at least one fourth path which is arranged in parallel with the third path,
wherein, a third bending section of the third path is bent into a lower plane than a fourth bending section of the fourth path, or the third bending section and the fourth bending section are bent in a corresponding manner to the first bending section.

7. The method according to claim 6, comprising:
bending the third bending section and the fourth bending section of the second path section such that the path section and the second path section are arranged adjacently to one another or one behind the other.

8. The method according to claim 5, comprising:
contact-connecting the first bending section of the first path with the terminal for the second electrical potential of the electrical or electronic component to produce the electrical or electronic module.

9. The method according to claim 8, comprising:
removing the edge region of the sheet metal blank or the pre-machined sheet-metal element, wherein the edge region is cut off, removed by laser cutting, and/or stamped off.

10. An apparatus for manufacturing a terminal apparatus, the apparatus comprising at least one processing device configured to:
execute and/or actuate the manufacture of the terminal apparatus at least by outputting signals to cause bending of a pre-machined sheet metal element comprising:
a first electric terminal device configured to connect to a first electrical potential;
a control terminal having at least one control contact; and
a second electric terminal device arranged between the first electric terminal device and the control terminal and separated from the first electric terminal device by a gap, wherein the second electric terminal device is configured to connect to a second electrical potential,
wherein the second electric terminal device has a path section which comprises a first path for contact-connection with a terminal for the second electrical potential of the electrical or electronic component, and/or at least one second path which is arranged in parallel with the first path, and
wherein the bending includes bending an edge region of the sheet metal such that the first electric terminal device and the path section are brought together, such that the first electric terminal device and the path section are arranged with an overlap.

11. A non-transitory machine-readable storage medium, on which a computer program is stored that, when executed by a processing device, cause the processing device to execute and/or actuate manufacture of a terminal apparatus at least by outputting signals to cause bending of a pre-machined sheet metal element comprising:
a first electric terminal device configured to connect to a first electrical potential;
a control terminal having at least one control contact; and
a second electric terminal device arranged between the first electric terminal device and the control terminal and separated from the first electric terminal device by a gap, wherein the second electric terminal device is configured to connect to a second electrical potential,
wherein the second electric terminal device has a path section which comprises a first path for contact-connection with a terminal for the second electrical potential of the electrical or electronic component, and/or at least one second path which is arranged in parallel with the first path, and
wherein the bending includes bending an edge region of the sheet metal such that the first electric terminal device and the path section are brought together, such that the first electric terminal device and the path section are arranged with an overlap.

12. A power converter comprising a terminal apparatus which has been manufactured according to the method according to claim 1.

13. An electric axle drive for a motor vehicle comprising at least one electrical machine, a transmission device, and a power converter according to claim 12.

14. A motor vehicle comprising an electric axle drive according to claim 13.
